(19) United States
(12) Patent Application Publication
(10) Pub. No.: US 2007/0077751 A1
(43) Pub. Date: Apr. 5, 2007

(54) METHOD OF RESTORING LOW-K MATERIAL OR POROUS LOW-K LAYER

(76) Inventors: Mei-Ling Chen, Kaohsiung City (TW); Jei-Ming Chen, Taipei County (TW); Kuo-Chih Lai, Tainan City (TW); Wen-Chieh Su, Tainan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/163,051

(22) Filed: Oct. 3, 2005

(51) Int. Cl. H01L 21/4763

(52) U.S. Cl. 438/622; 438/626

(57) ABSTRACT

A method of restoring a low-k material is described, applied to a substrate with a low-k material thereon, wherein the substrate has been subject to a previous process that raised the k-value of the low-k material. The method includes performing a plasma treatment to the low-k material to decrease the k-value thereof.

### BACKGROUND OF THE INVENTION

1. Field of the Invention

The present invention relates to a method of processing a low-dielectric-constant (low-k) material. More particularly, the present invention relates to a method of restoring the dielectric constant (k-value) of a low-k material.

2. Description of the Related Art

In the rapid development of ultra-large scale integrated circuits, low-k material has become a very important factor in reducing the RC delay effect of the interconnect structure to increase the operation speed.

To make the k-value of a dielectric layer closer to that of air, many porous low-k materials with nanopores or sub-nanometer pores therein have been studied. However, a porous low-k material easily adsorbs moisture, gas or other contaminant during an etching, ashing, washing or chemical mechanical polishing (CMP) process, so that the k-value thereof is raised degrading the original low-k property thereof.

For example, in a damascene process, the metal-CMP step is usually continued after the metal polishing to polish the hard mask layer down to the surface of the low-k layer. Thus, the k-value of the low-k layer may be raised by more than 10% relative to that before the CMP process.

### SUMMARY OF THE INVENTION

In view of the foregoing, this invention provides a method of restoring a low-k material, which can lower the k-value of the low-k material that has been raised by a previous process.

This invention also provides a method of restoring a porous low-k layer, which can lower the k-value of the porous low-k layer having been raised by a CMP process.

The method of restoring a low-k material of this invention is done to a substrate with a low-k material thereon, which has been subject to a previous process that raised the k-value of the low-k material. The method includes conducting a plasma treatment to lower the k-value of the low-k material that has been raised.

The low-k material may have a k-value of about 1.0-2.7 and may be a porous low-k material, such as carbon-doped oxide (CDO) that contains a porogen like a hydrocarbon compound (CₓH_{y}). The low-k material may be formed through spin-coating or plasma enhanced chemical vapor deposition (PECVD), and the previous process may be an etching, washing, ashing or CMP process. The plasma treatment may be conducted in a PECVD chamber or a sub-atmospheric pressure chemical vapor deposition (SACVD) chamber, and can be conducted in-situ or ex-situ after the previous process.

In addition, the plasma treatment may use a oxygen-containing gas, a carbon-containing gas, a nitrogen-containing gas, a hydrogen-containing gas or an inert gas as a plasma-generating gas. In the plasma treatment, the pressure may be set at about 2.5-25 Torr, the flow rate of the plasma-generating gas may be set at about 100-100,000 sccm, the temperature may be set at about 200-450° C., and the RF power source used is possibly a single-frequency or dual-frequency RF power source that may provide a power of about 50-3000 W in the plasma treatment.

The method of restoring a porous low-k layer of this invention is applied to a substrate with at least a device and a porous low-k layer thereon, which has been subject to a CMP process that was conducted at least down to the surface of the porous low-k layer and thereby raised the k-value of the same. The method includes conducting a plasma treatment to the porous low-k layer to lower the k-value thereof.

In the above method of restoring a porous low-k layer, other features about the porous low-k layer and the plasma treatment can be similar to those mentioned above.

By conducting a plasma treatment to a low-k material after the k-value thereof is raised by a previous process like an etching, washing, ashing or CMP process, the low dielectricity of the low-k material can be restored to prevent the RC delay time from being increased and maintain the operation speed.

It is to be understood that both the foregoing general description and the following detailed description are exemplary, and are intended to provide further explanation of the invention as claimed.

### BRIEF DESCRIPTION OF THE DRAWINGS

FIG. 1 is a flow chart of a method of restoring a low-k material according to an embodiment of this invention.

FIG. 2 is a flow chart of a method of restoring a porous low-k layer after a CMP process according to a further embodiment of this invention.

FIG. 3 shows the changes of the k-value of the porous low-k layer after the CMP process and after the plasma treatment process according to the further embodiment.

### DESCRIPTION OF THE PREFERRED EMBODIMENTS

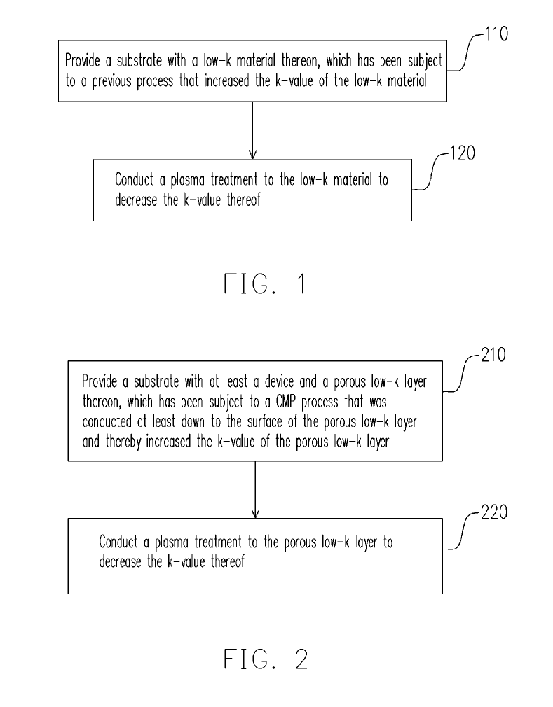

FIG. 1 is a flow chart of a method of restoring a low-k material according to an embodiment of this invention. In step 110, a substrate with a low-k material thereon is provided, which has been subject to a previous process that raised the k-value of the low-k material. The substrate may have a device therein, such as a MOS transistor or a memory device, and the low-k material may constitute an IMD layer covering a device. The low-k material can be a porous low-k material possibly having a k-value of about 1.0-2.7, such as, carbon-doped oxide (CDO) containing a porogen like a hydrocarbon compound (CₓH_{y}), fluorinated amorphous carbon, Parylene AF4, PAE or Cyclotene, etc. The low-k material may be formed through spin-coating, PECVD or high-density plasma (HDP) CVD. The previous process is possibly an etching, washing, ashing or CMP process that raised the k-value of the low-k material by more than 10%.

In next step 120, a plasma treatment is conducted to the low-k material to lower the k-value of the same. After the plasma treatment, the k-value of the low-k material is usually higher than that before the previous process by merely 4% or less. The plasma treatment can be conducted in a PECVD, HDP-CVD or SACVD chamber, usually after a plasma etching process conducted to the substrate in the same chamber.

In addition, the plasma-generating gas used in the plasma treatment can be an oxygen-containing gas or a carbon-containing gas like CO₂ or O₂, a nitrogen-containing gas like NH₃, a hydrogen-containing gas like H₂, or an inert gas like He or Ar. In the plasma treatment, the pressure in the reaction chamber may be set at about 2.5-25 Torr, the flow rate of plasma-generating gas may be set at about 100-100,000 sccm, and the temperature may be set at about 200-450° C. The plasma treatment can be conducted in the same reaction chamber used in the previous process (in-situ) or at a different location (ex-situ) after the previous process. Moreover, The RF power source used in the plasma treatment can be a single-frequency or dual- frequency RF power source, of which the power may be set at about 50 W to 3000 W according to the species of the plasma-generating gas.

Through the above plasma treatment, the k-value of the low-k material having been raised by a previous process can be lowered, so that the low dielectricity of the low-k material can be restored to meet certain requirements. For example, the plasma- treated low-k material can be combined with a low-resistance metal like copper to solve the RC delay problem of interconnect structures.

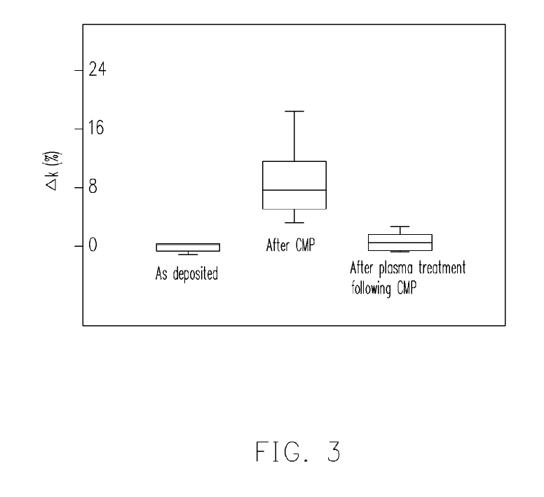

FIG. 2 is a flow chart of a method of restoring a porous low-k layer after a CMP process according to a further embodiment, and FIG. 3 shows the changes of the k-value of the porous low-k layer after the CMP process and after the later plasma treatment in an example of this invention.

Referring to FIG. 2, in step 210, a substrate with at least a device and a porous low-k layer thereon is provided, which has been subject to a CMP process that was conducted at least down to the surface of the porous low-k layer and thereby raised the k-value of the same. The porous low-k layer may serve as an IMD layer, under which a MOS transistor or a memory device may have been formed previously. The material of the porous low-k layer may be a porous dielectric material having a k-value of about 1.0-2.7, such as, carbon-doped oxide containing a porogen like CₓH_{y}, fluorinated amorphous carbon, Parylene AF4, PAE or Cyclotene, etc. The porous low-k layer may be formed through spin-coating or PECVD, while the CMP process was performed possibly for removing a hard mask layer used to define the low-k material layer. The material of the hard mask layer may be silicon carbide.

Moreover, the porous low-k layer may have an opening therein, which is, for example, a dual-damascene opening, a via hole or a contact hole. The opening may have been filled with an adhesive/barrier layer and a metal layer, wherein the adhesive/barrier layer may include Ti/TiN and the metal layer may include copper.

It is noted that a CMP process generally utilizes a complex mechanical-chemical mechanism for polishing, so that quite a few chemical bonds at the surface of the porous low-k layer are broken to form dangling bonds. Because the dangling bonds are not stable, they are readily bonded with polar functional groups like —OH or —NH₂ in the environment to raise the k-value of the porous low-k layer. As shown in FIG. 3, the k-value of the porous low-k layer is raised by more than 10% after the CMP process.

In next step 220, a plasma treatment is conducted to the porous low-k layer to lower the k-value of the same. The plasma treatment can be conducted in a PECVD, HDP-CVD or SACVD chamber, possibly after a plasma etching process conducted to the substrate in the same chamber. Moreover, the species and flow rate of the plasma generating gas, the type of the RF power source, the pressure, temperature and the mode (in-situ or ex-situ) of the above plasma treatment can be the same as the above.

For example, in a plasma treatment for test, helium gas is used as a plasma-generating gas and a RF power of 250 W is applied for 30 seconds to lower the k-value of a porous low-k layer. With the plasma treatment, the k-value of the porous low-k layer is lowered to be higher than that before the CMP process by merely 2% or less.

The above plasma treatment is capable of breaking the bonding between the polar functional groups and the surface of the porous low-k layer to restore the chemical structure and low dielectricity of the same, i.e., to lower the k-value thereof that has been raised. As shown in FIG. 3, the plasma treatment can almost compensate the raise in k-value caused by the previous CMP process, so that the k-value after the plasma treatment is quite close to that before the CMP process.

Accordingly, by conducting a plasma treatment to a porous low-k layer after the k-value thereof is raised by a previous CMP process, the low dielectricity of the same can be restored to prevent the RC delay time from being increased and prevent the operation speed from being decreased.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A method of restoring a low-k material, applied to a substrate with a low-k material thereon, wherein the substrate has been subject to a previous process that raised the k-value of the low-k material, the method comprising:
conducting a plasma treatment to the low-k material to lower the k-value thereof that has been raised by the previous process.

2. The method of claim 1, wherein the k-value of the low-k material is about 1.0 to 2.7.

3. The method of claim 1, wherein the low-k material comprises a porous low-k material.

4. The method of claim 3, wherein the porous low-k material comprises carbon- doped oxide (CDO) that contains a porogen.

5. The method of claim 1, wherein the low-k material is formed through spin-coating or PECVD.

6. The method of claim 1, wherein the previous process comprises an etching process, a washing process, an ashing process or a CMP process.

7. The method of claim 1, wherein the plasma treatment is conducted in a PECVD chamber or a SACVD chamber.

8. The method of claim 1, wherein the previous process is conducted in a reaction chamber, and the plasma treatment is conducted in the same reaction chamber (in-situ) or at a different location (ex-situ) after the previous process.

9. The method of claim 1, wherein a plasma-generating gas used in the plasma treatment comprises an oxygen-containing gas, a carbon-containing gas, a nitrogen-containing gas, a hydrogen-containing gas or an inert gas.

10. The method of claim 9, wherein a pressure of the plasma treatment is set at about 2.5 Torr to 25 Torr.

11. The method of claim 9, wherein a flow rate of the plasma-generating gas is set at about 100 sccm to 100,000 sccm.

12. The method of claim 1, wherein a temperature of the plasma treatment is set at about 200° C. to 450° C.

13. The method of claim 1, wherein the plasma treatment uses a single-frequency RF power source or a dual-frequency RF power source as a RF power source.

14. The method of claim 13, wherein a power applied by the RF power source in the plasma treatment is set at about 50 W to 3000 W.

15. A method of restoring a porous low-k layer, applied to a substrate with at least a device and a porous low-k layer thereon, wherein the substrate has been subject to a CMP process that was conducted at least down to the surface of the porous low-k layer and thereby raised the k-value of the same, the method comprising:
conducting a plasma treatment to the porous low-k layer to lower the k-value thereof.

16. The method of claim 15, wherein the k-value of the porous low-k layer is about 1.0 to 2.7.

17. The method of claim 15, wherein the porous low-k layer comprises carbon-doped oxide (CDO) that contains a porogen.

18. The method of claim 15, wherein the plasma treatment is conducted in a PECVD chamber or a SACVD chamber.

19. The method of claim 15, wherein a plasma-generating gas used in the plasma treatment comprises an oxygen-containing gas, a carbon-containing gas, a nitrogen- containing gas, a hydrogen-containing gas or an inert gas.

20. The method of claim 19, wherein a pressure of the plasma treatment is set at about 2.5 Torr to 25 Torr.

21. The method of claim 19, wherein a flow rate of the plasma-generating gas is set at about 100 sccm to 100,000 sccm.

22. The method of claim 15, wherein a temperature of the plasma treatment is set at about 200° C. to 450° C.

23. The method of claim 15, wherein the plasma treatment applies a RF power of about 50-3000 W.

24. The method of claim 15, wherein the porous low-k layer is formed through spin-coating or PECVD.
